(19) United States
(12) Patent Application Publication
(10) Pub. No.: US 2019/0181116 A1
(43) Pub. Date: Jun. 13, 2019

(54) FAN-OUT STRUCTURE FOR SEMICONDUCTOR PACKAGES AND RELATED METHODS

(71) Applicant: SEMICONDUCTOR COMPONENTS INDUSTRIES, LLC, Phoenix, AZ (US)

(72) Inventor: Yusheng LIN, Phoenix, AZ (US)

(73) Assignee: SEMICONDUCTOR COMPONENTS INDUSTRIES, LLC, Phoenix, AZ (US)

(21) Appl. No.: 15/837,857

(22) Filed: Dec. 11, 2017

(51) Int. Cl. H01L 23/00; H01L 23/538; H01L 23/31; H01L 23/373; H01L 21/48; H01L 21/56; H01L 21/78

(52) U.S. Cl. CPC H01L 24/96; H01L 23/5389; H01L 23/5386; H01L 23/3114; H01L 23/3736; H01L 24/20; H01L 2224/214; H01L 21/561; H01L 21/565; H01L 21/568; H01L 21/4871; H01L 21/78; H01L 21/4853

(57) ABSTRACT

Implementations of semiconductor packages may include: one or more die having a first side and a second side opposite the first side; the first side of the die may include one or more external connection points; a layer of one or more metals comprised on the second side of the one or more die; a second layer of one or more metals comprised on the first layer of one or more metals, wherein the second layer is thicker than the first layer; a molding compound encapsulating five sides of the one or more die and partially encapsulating the second layer of a metal; a plurality of interconnects coupled to the second layer of one or more metals; and two or more bumps coupled to the plurality of interconnects. At least a portion of each of the two or more bumps may be outside a perimeter of the one or more die.

### BACKGROUND

### 1. Technical Field

Aspects of this document relate generally to semiconductor packages, such as chip scale packages. More specific implementations involve flip chip packages.

### 2. Background

Conventionally, fan-out chip scale packages can have five sides of protection. Some packages contain a single die while others contain multiple die. Some packages include ball grid arrays or land grid arrays.

### SUMMARY

Implementations of semiconductor packages may include: one or more die having a first side and a second side opposite the first side; the first side of the die may include one or more external connection points; a layer of one or more metals comprised on the second side of the one or more die; a second layer of one or more metals comprised on the first layer of one or more metals, wherein the second layer is thicker than the first layer; a molding compound encapsulating five sides of the one or more die and partially encapsulating the second layer of a metal; a plurality of interconnects coupled to the second layer of one or more metals; and two or more bumps coupled to the plurality of interconnects. At least a portion of each of the two or more bumps may be outside a perimeter of the one or more die.

Implementations of semiconductor packages may include one, all, or any of the following:

The two or more bumps may include copper pillars, balls, solder printed pads, or pads.

The semiconductor package may also include a first passivation layer or a redistribution layer (RDL).

The semiconductor package may also include a second passivation layer coupled to the first passivation layer or the redistribution layer.

The semiconductor package may also include a second molding compound on the first side of the one or more die.

The semiconductor package may also include a metal coating on the one or more external connection points of the first side of the one or more die, the metal coating selected from the group consisting of titanium, nickel, vanadium, silver, copper, gold, aluminum, or any combination thereof.

The semiconductor package may also include a copper plating or a copper frame on the one or more external connection points of first side of the die.

Implementations of semiconductor packages may include: one or more die having a first side and a second side opposite the first side; two or more copper pillars coupled on a second side of the one or more die; a layer of aluminum coupled between the one or more die and each of the two or more copper pillars; a molding compound encapsulating five sides of the one or more die and partially encapsulating the two or more copper pillars; a routing layer of metal coupled to the two or more copper pillars; and a plurality of solder bumps coupled to the routing layer. At least a portion of the solder bumps may be outside a perimeter of the one or more die.

Implementations of semiconductor packages may include one, all, or any of the following:

The semiconductor package may also include a first passivation layer or a redistribution layer (RDL).

The semiconductor package may also include a second passivation layer coupled to the first passivation layer or the redistribution layer.

The semiconductor package may also include a second molding compound on the first side of the one or more die.

The semiconductor package may also include a metal coating on the first side of the one or more die, the metal coating selected from the group consisting of titanium, nickel, vanadium, silver, copper, gold, aluminum, or any combination thereof.

The semiconductor package may also include a copper plating or a copper frame on a first side of the die.

Implementations of a method of manufacturing semiconductor packages may include: providing a wafer having a plurality of die. Each die may include a first side and a second side. The method may also include plating two or more copper pillars on the second side of each of the plurality of die. A layer of aluminum may be included between each of the copper pillars and the first side of each of the plurality of die. The method may also include encapsulating the plurality of die in a molding compound, exposing a second side of the two or more copper pillars through grinding the molding compound, and applying a plurality of interconnects to the molding compound comprised on the second side of the die. The plurality of interconnects may be electrically coupled to the copper pillars through metal plating.

Implementations of semiconductor packages may include one, all, or any of the following:

The method may further include applying a first passivation layer or a redistribution layer (RDL) to a second side of the molding compound on the second side of the die.

The method may further include applying a second passivation layer to the first passivation layer or a redistribution layer (RDL) to a second side of the molding compound comprised on the second side of the die.

The method may further include singulating the plurality of die after plating the plating two or more copper pillars; coupling a carrier to the second side of each of the plurality of die; and removing the carrier after encapsulating the plurality of die in a molding compound.

The method may further include thinning a second side of each of the plurality of die and applying a coating to the first side of the plurality of die.

The coating on the first side of the die may include a metal coating, the metal coating selected from the group consisting of titanium, nickel, silver, copper, gold, aluminum, and any combination thereof.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is an implementation of a fan-out semiconductor package having a backside coat or equivalent encapsulation materials;

FIG. 2 is an implementation of a fan-out semiconductor package having a back metallization through sputter or evaporation;

FIG. 3 is an implementation of a fan-out semiconductor package having a thick backside metallization through copper plating or copper frame attachment;

FIG. 4 is an implementation of a fan-out semiconductor package having two die and a backside coat or equivalent encapsulation materials;

FIG. 5 is an implementation of a fan-out semiconductor package having two die and a back metallization through sputter or evaporation;

FIG. 6 is an implementation of a semiconductor package having two die and a thick backside metallization through copper plating or copper frame attachment;

FIGS. 7A-7H is an implementation of a method of forming a fan-out semiconductor package;

FIGS. 8A-8H is another implementation of a method of forming a fan-out semiconductor package; and

FIGS. 9A-9H is another implementation of a method of forming a fan-out semiconductor package.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

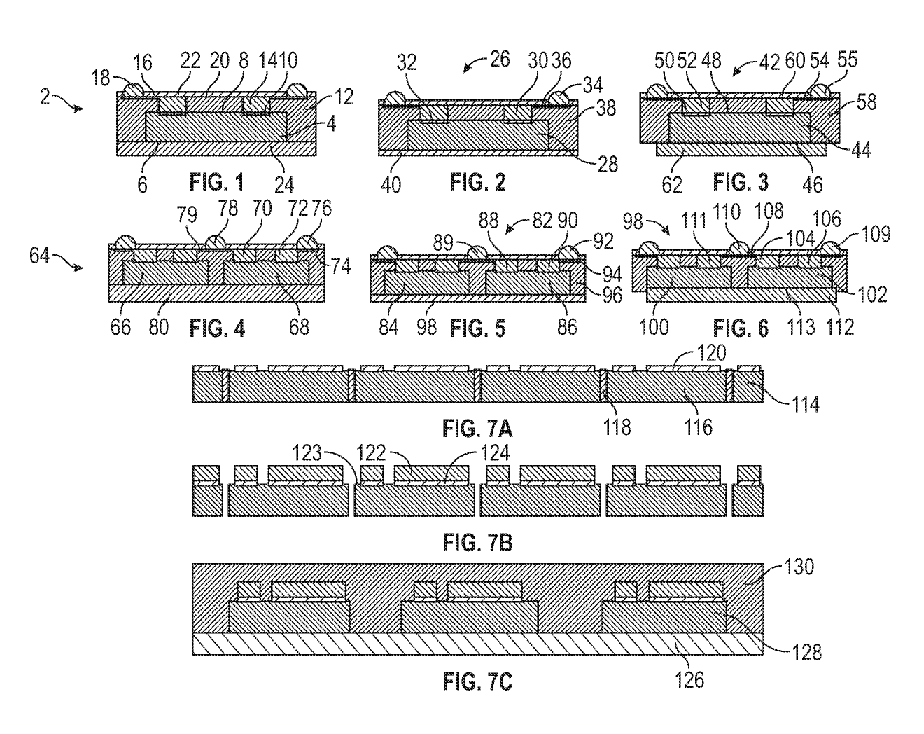

Referring to FIG. 1, an implementation of a semiconductor package 2 is illustrated. The package 2 includes one die 4 having a first side 6 and a second side 8. The first side of the die may include one or more external connection points. In various implementations, the die may be formed from silicon (Si), silicon germanium (SiGe), gallium nitride (GaN), silicon carbon (SiC), silicon on insulator (SOI), sapphire, ruby, gallium arsenide, or any other semiconductor substrate material. In some implementations, a hard semiconductor material such as SiC is preferred. The package also includes a layer of metal 10 on the second side of the die. In various implementations, the layer of metal may include aluminum (Al), though any other metal or metal alloy may be used in various implementations. In some implementations, the layer of metal may include one or more metals, either as separate layers of individual elemental metals or in the form of one or more metal alloys. As illustrated, a second, thicker, layer of metal 14 is included on the first layer of metal 10. The second layer of metal may include in various implementations, copper (Cu) pillars, solder formed using solder ball drop and solder printing, nickel (Ni), gold (Au), or any combination thereof. Where nickel or gold are used, the nickel or gold may be formed in a surface land grid array (LGA). In various implementations, the second layer of metal may include one or more metals, which may be either separate layers of individual elemental metals or one or more metal alloys.

As illustrated in FIG. 1, a molding compound 12 encapsulates the second side or active side of the die and gives protection to five sides of the die 4. The molding compound also partially encapsulates the second layer of the metal 14. In various implementations, the molding compound may include a thermosetting or thermoplastic polymer, a thermosetting resin, an epoxy resin, and other polymeric or composite flowable material. As shown, a plurality of interconnects 16 are coupled to the second metal layer 14 and two bumps 18 are coupled to the plurality of interconnects 16. In some implementations, the plurality of interconnects may be routed through the one or more passivation layers. In various implementations, the bumps may include copper pillars, balls, solder printed pads, and pads. In some implementations, the package may include more than two bumps. At least a portion of each of the two or more bumps is outside a perimeter of the die giving the package a fan-out structure.

As illustrated, the package also includes a first passivation layer 22 coupled to the molding compound 12. In various implementations, a redistribution layer (RDL) may be used in place of a passivation layer. By non-limiting example, the redistribution layer may be an electrically conductive redistribution layer. In various implementations, the electrically conduction RDL may be routed through the passivation layer(s). In some implementations of semiconductor packages as described herein, there may not be a first passivation layer or a redistribution layer. In still other implementations, a second passivation layer may be coupled to a first passivation layer or to a redistribution layer. By non-limiting example, the second passivation layer may be used to reveal external connection points of the die. In this particular implementation, a second molding compound 24 is coupled to the first side of the die. In other implementations, there may not be a second molding compound coupled to the first side of the die.

Referring to FIG. 2, another implementation of a semiconductor package 26 is illustrated. The semiconductor package 26 includes a single die 28 having a first side and a second side. In various implementations, a semiconductor package as disclosed herein may include two or more die. The package 26 includes two copper pillars 30 or equivalent metal pillars coupled on a second side of the die with a layer of aluminum 32 coupled between the die 28 and the copper pillars 30. In other implementations, packages may include more than two copper pillars. In various implementations of the package, metals besides copper may be used such as, by non-limiting example, solder balls, solder printing, Ni/Au surface land grid array (LGA), or other metals that help to dissipate heat from the package. The copper pillars 30 are electrically and mechanically coupled with two solder bumps 34 through a routing layer of metal 36. As illustrated, the two solder bumps 34 are located substantially outside a perimeter of the die 28. The package also includes a molding compound 38 encapsulating at least five sides of the die and partially encapsulating the two copper pillars 30. In various implementations, the molding compound may include various materials as previously described.

In this particular implementation, the package includes a metal coating 40 on the first side of the die. The metal coating may be on the external connection points of the first side of the die. The metal coating 40 may help to further dissipate heat or to make electrical conduction to the first side from the package. In various implementations, the metal coating may include titanium, nickel, vanadium, silver, copper, gold, aluminum, and any combination thereof. Specific combinations may include NiV and AgCuAu metal coating layers. The metal coating may be applied to the semiconductor package using sputtering techniques, evaporating techniques, or any suitable methods for applying metal to a surface of a device.

The dual side metallization illustrated in this implementation of a semiconductor package and others as described herein may also improve drain-source on resistance (Rdson), source to source on state resistance (Rsson), and die to die interconnection. The dual side metallization fan-out technology described herein may be used in many different semiconductor devices including metal oxide semiconductor field effect transistors (MOSFETs), insulated-gate bipolar transistors (IGBTs), gallium nitride (GaN) devices having a single die or multiple die, silicon carbon (SiC) devices having single or multiple die, or semiconductor devices that create excessive heat during operation. This technology may also be used with any flip chip configuration including, but not limited to, Cu pillars, ball drops, solder print, or Ni/Au surface land grid array.

Referring to FIG. 3, another implementation of a semiconductor package 42 as described herein is illustrated. The package includes one semiconductor die 44 having a first side 46 and a second side 48. Coupled to the second side of the die is a first layer of a metal 50. In various implementations, the first layer of a metal may include aluminum. A second layer 52 of a metal is layered on the first layer of a metal and the second layer of a metal is thicker than the first layer. In various implementations, the first layer of a metal and the second layer of a metal may be different metals or the layers may both include the same metal. A plurality of interconnects 54 are coupled to the second metal layer 52 which couple each of the second layers 52 of metal to a bump 55. In various implementations, there may be more than one or two bumps 55 coupled to each second layer of metal 52 through interconnects. The bumps may include solder balls, copper pillars, solder printed pads, or other pads that carry the electrical connection of the second metal layer to connections outside the package. The bumps are located outside the perimeter of the die.

As illustrated in FIG. 3, the package 42 also includes a molding compound 58 around at least five sides of the die. The molding compound also encapsulates the second layer of metal 52. The molding compound 58 may be a thickness that allows flexibility of the package to reduce thermal mechanical stress during processing of the packages. In various implementations, the molding compound may include resins, epoxy resins, and other molding compounds as previously described that would provide flexibility in the semiconductor package. As shown in FIG. 3, the package also includes a redistribution layer 60 on the active side or second side 48 of the die. In other implementations, the package may include a first passivation layer as previously described. In still other implementations, the package may include a passivation layer on the redistribution layer or a second passivation layer on the first passivation layer.

Referring to the first side 46 of the die of the package in FIG. 3, a copper plating 62 is illustrated coupled to the first side of the die. The copper plating may further increase thermal dissipation of the package acting as a heat sink. In various implementations, the copper plating may include pure copper, copper with nickel and/or gold, or copper with aluminum. However, in various implementations, copper may not be used, but any other platable metal or metal alloy or any other metal or metal layer that can be attached as a foil layer may be employed. Further implementations of plating metals and techniques used to increase thermal dissipation can be found in U.S. Pat. No. 9,397,017, entitled “Substrate Structures and Methods of Manufacture” to Lin et. al., issued Jul. 19, 2016, and U.S. Pat. No. 9,640,497, entitled “Semiconductor Backmetal (BM) and Over Pad Metallization (OPM) structures and related methods” to Lin et. al., issued May 2, 2017, the entirety of each of which is hereby incorporated entirely herein by reference.

Referring to FIG. 4, an implementation of a semiconductor package 64 having two die 66 and 68 is illustrated. In this particular implementation, each die includes two second metal layers 70 and 72 on the second side of each of the die 66 and 68. In various implementations, a first layer of metal may be between the second side of the die and the second metal layer. The second metal layers are coupled to a plurality of interconnects 74 that connect the second metal layers to two bumps 76 that extend at least partially beyond an outside perimeter of each of the die. Here, one bump 78 is located between the two die 66 and 68 and the bump 78 is coupled to metal layers 70 on each die through interconnects 79. In other implementations, there may be more than two bumps per die in a package. As previously explained, the bumps may be copper pillars, balls, solder printed pads, or pads, or any combination of the foregoing.

Referring to FIG. 5, an implementation of a semiconductor package 82 having two die 84 and 86 is illustrated. In this particular implementation, each die includes two second metal layers 88 and 90 on the second side of the die. A first layer of metal may be between the second side of the die and the second metal layer. The second metal layers 88 and 90 are coupled to a plurality of interconnects 94 that connect the second metal layers 88 and 90 to bumps 92 on an outside perimeter of each of the die. In implementations including more than one die, at least one bump 89 is located between the die and coupled to the second metal layers on each die through interconnects. In other implementations, there may be more than two bumps per die in a package and there may be more than one bump in between the die.

In this particular implementation, the package includes a metal coating 98 on the first side of the die 84 and 86. The metal coating 98 may help to further dissipate heat from the package. As previously described in various implementations, the metal coating may include titanium, nickel, vanadium, silver, copper, gold, aluminum, and any combination thereof. Specific combinations may include NiV and AgCuAu metal coating layers. The metal coating may be applied to the semiconductor package using sputtering techniques, evaporating techniques, plating, or any suitable methods for applying metal to a surface.

Referring to FIG. 6, another implementation of a semiconductor package 98 having two die 100 and 102 is illustrated. In this particular implementation, each die includes two second metal layers 104 and 106 on the second side of the die. A first layer of metal may be between the second side of the die and the second metal layer. The second metal layers 104 and 106 are coupled to a plurality of interconnects 108 that connect the second metal layers 104 and 106 to bumps 109 and 110 on an outside perimeter of each of the die. In various implementations, at least a portion of the bumps are outside the perimeter of the die. In implementations including more than one die, at least one bump 110 is located between the die and coupled to metal layers 104 and 111 on each die through interconnects 108. In other implementations, there may be more than two bumps per die in a package.

As illustrated in FIG. 6, on the first side of the two die 100 and 102 a metal plating layer 112 is illustrated coupled to the first side 113 of the die. The metal plating layer 112 may further increase thermal dissipation of the package acting as a heat sink, or otherwise assisting with thermal transfer to a heat sink attached to the layer. In various implementations, the metal plating may include any metal disclosed herein including pure copper, copper with nickel and/or gold, or copper with aluminum. The copper may be applied to the semiconductor package through various plating techniques. In other implementations, the copper plate may include a copper frame. In other implementations, as previously disclosed, the metal may be applied using a metal foil.

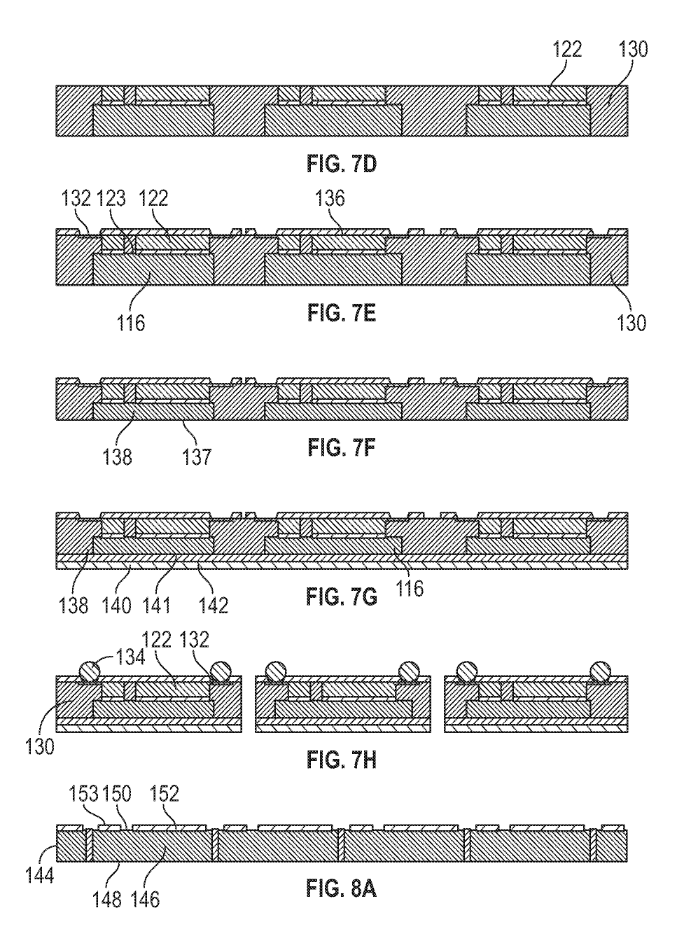

Referring to FIG. 7A-7H, a method for manufacturing a semiconductor is illustrated. In FIG. 7A, a wafer 114 is provided. The wafer includes a plurality of die 116 where each die has a first side and a second side. In various implementations, the wafers may include Si, GaN, SiC, or another suitable semiconductor substrate material disclosed herein. For illustrative purposes, the wafer is shown having each die separated by a scribe line 118. Each die includes an active area 120 which are illustrated here having different sizes. In various implementations, the active areas may include a source, a drain, and a gate. In other implementations, the active areas may be the same size as illustrated in previous implementations.

Referring to FIG. 7B, the method may further include plating two or more copper pillars 122 on the second side 123 of each of the plurality of die. In various implementations, a different metal may be used in place of copper pillars. The different metal may include solder, Ni, Au, or any other metal or metal alloy. A layer of aluminum 124 may be included between each of the copper pillars 122 and the first side 123 of each of the plurality of die. As shown in FIG. 7B, the die may then be singulated from each other at the scribe lines. In other implementations of a method of forming semiconductor packages, the die may be singulated at a later step in the manufacturing process.

Referring to FIG. 7C, the plurality of die are then coupled to a carrier wafer 126 to provide stability. The method further includes encapsulating the plurality of die 128 in a molding compound 130. The molding compound 130 may include a material that allows flexibility of the packages during the manufacturing process as previously described. The carrier wafer 126 may be removed after the molding compound has cured. In various implementations, the carrier wafer may not be used when the die are not singulated until the end of the method of manufacturing a semiconductor package. As illustrated in FIG. 7D, the method includes grinding the molding compound to a desired thickness and exposing a first side of the copper pillars 122.

Referring to FIG. 7E, the method further includes applying a plurality of metal plating 132 to the molding 130 on the second side 123 of each of the die 116. The plurality of metal plating mechanically and electrically couples the copper pillars 122 to the plurality of bumps 134 as illustrated in FIG. 7H. In various implementations, this plurality of metal plating forms the traces for the “fan out” of the package. The plurality of metal plating may include any metal or metal alloy that is a good electrical conductor. As illustrated in FIG. 7E, the method may include applying a first passivation layer or a redistribution layer 136 to a second side of the molding compound 130. In various implementations, the method may further include applying a second passivation layer to the first passivation layer or redistribution layer.

Referring to FIG. 7F, the method may, some implementations, include thinning a first side 137 of each of the plurality of die 138. Thinning of the first side 137 of the die together with thinning the molding compound 130 may give the semiconductor package increased flexibility especially in power devices. Referring to FIG. 7G, the method may further include applying a coating 140 to the first side 138 of the plurality of die 116. In various implementations, the coating may include a metal. The metal may be applied through sputtering, evaporation, or other methods for applying metal to a surface. In some implementations, the metal coating may include a foil that is patterned on the first side of the plurality of die. As illustrated, the coating may be applied to the first surface of the plurality of die in multiple layers. In some implementations, a first layer 141 of metal coating may be applied through sputtering and a second metal 142 of metal coating may be applied through evaporation.

Referring to FIG. 7H, a plurality of bumps 134 is applied to the molding compound 130. The plurality of bumps 134 are mechanically and electrically coupled with the copper pillars 122 through metal plating 132 or interconnects. As illustrated, the plurality of die are singulated into individual semiconductor packages now having a fan out structure.

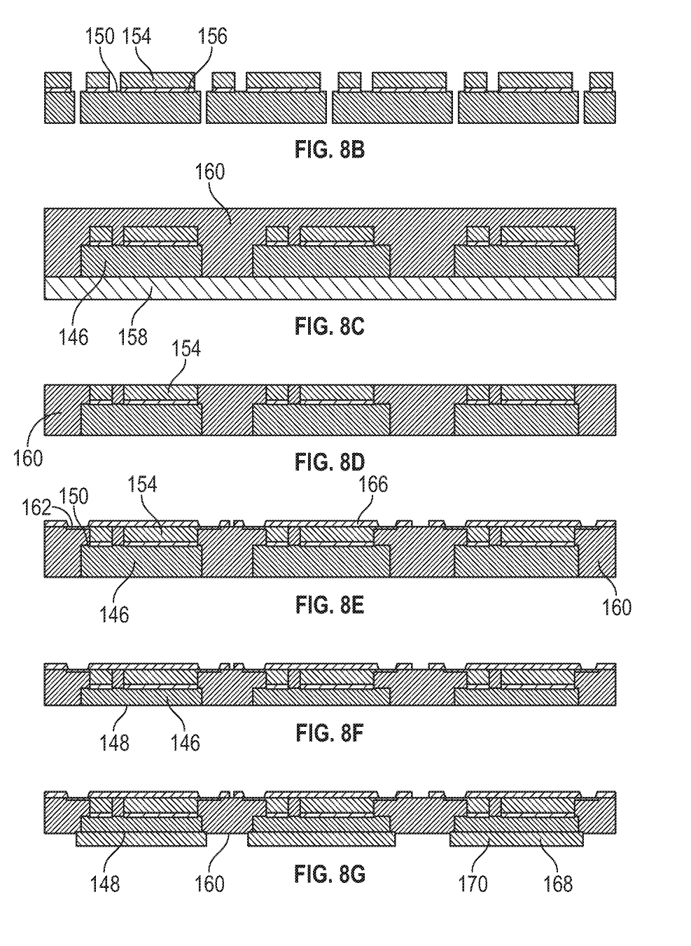

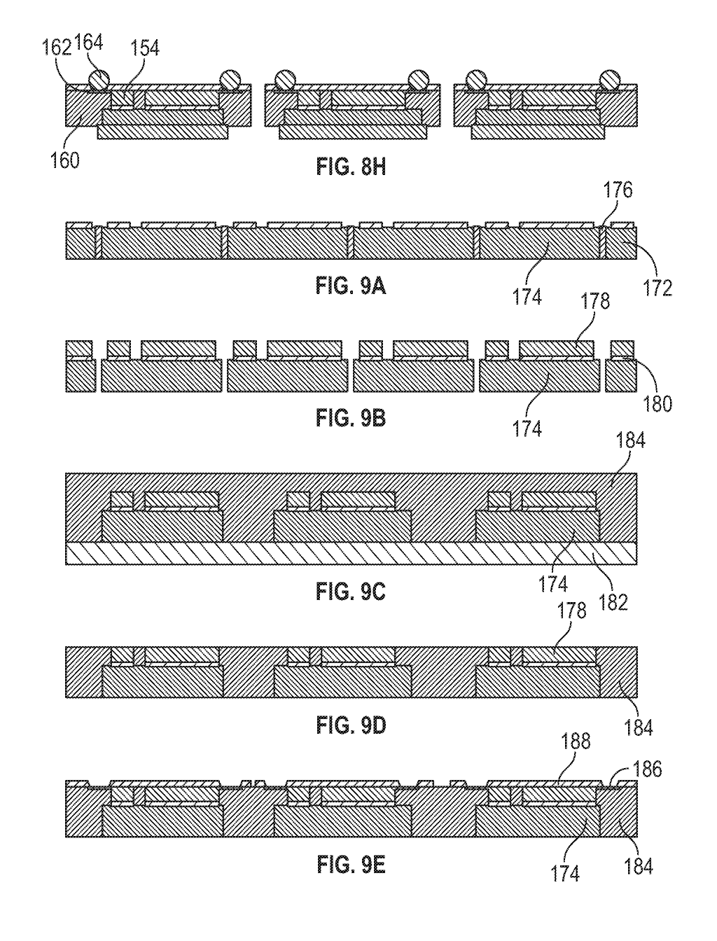

Referring to FIG. 8A-8H, another implementation of a method for manufacturing a semiconductor is illustrated. In FIG. 8A, a wafer 144 including a plurality of die is provided. Each die includes a first side 148 and a second side 150. As previously described various implementations, may include Si, GaN, or SiC wafers (or any other semiconductor substrate type disclosed herein). Each die includes two active areas 152 and 153. In various implementations, the active areas may include a source, drain, and a gate. In other variations, the die may include one active area or more than two active areas.

Referring to FIG. 8B, the method may further include plating two copper pillars 154 on the second side 150 of each of the plurality of die. In various implementations, more than two copper pillars may be plated on the second side of the die. A layer of aluminum 156 may be included between each of the copper pillars 154 and the second side 150 of the each of the plurality of die. In various implementations, a different metal may be used in place of copper pillars. The different metal may include solder, Ni, Au, or other suitable metals. As shown in FIG. 8B, the die may be singulated from each other on the scribe lines. In other implementations of a method of forming semiconductor packages, the dies may be singulated later in the method.

Referring to FIG. 8C, the plurality of die may be coupled to a carrier wafer 158 to provide support and stability during subsequent steps in the manufacturing process. The method may further include encapsulating the plurality of die 146 in a molding compound 160. The molding compound 160 may include a material that allows for flexibility of the packages and sufficient stiffness for subsequent steps of the manufacturing process. The molding compound may be any disclosed in this document. In various implementations, the carrier wafer 158 may be removed after the molding compound has cured. As illustrated in FIG. 8D, the method may include grinding the molding compound 160 to a desired thickness and exposing a second side of the copper pillars 154.

Referring to FIG. 8E, the method further includes forming a plurality of metal plating 162 to the molding compound 160 on the second side 150 of each of the die 146. The plurality of metal plating mechanically and electrically couples the copper pillars 154 to the plurality of bumps 164 as illustrated in FIG. 8H. The plurality of metal plating may include any metal that is an electrical conductor. As illustrated in FIG. 8E, the method may include applying a first passivation layer 166 to a second side of the molding compound 160. In various implementations, a redistribution layer may be applied to the second side of the molding compound. In other implementations, the method may further include applying a second passivation layer the first passivation layer or to the redistribution layer.

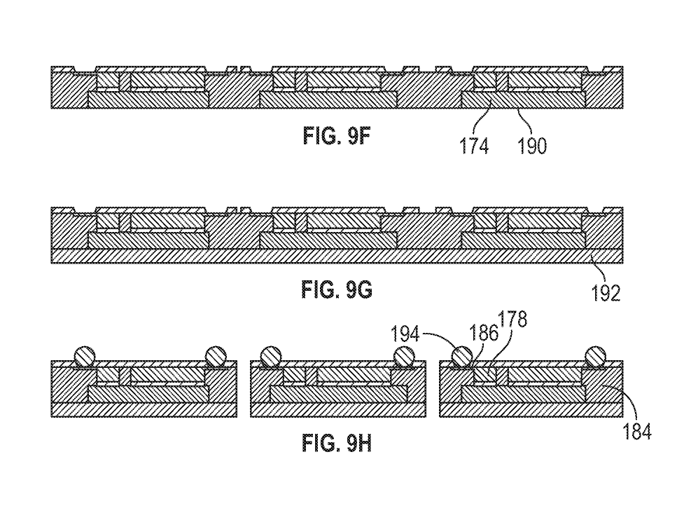

Referring to FIG. 8F, the method may include thinning a first side 148 of each of the plurality of die 146. Thinning of the first side of the die together with the molding compound may give the semiconductor package increased flexibility. The thinning may be done by grinding the die and the molding compound. Referring to FIG. 8G, the method may further include applying a coating 168 to the first side 148 of the plurality of die. As illustrated the coating may include a metal plating 170 such as a copper plate, copper slug, or copper frame. In other implementations, the metal plate may include other metals that help to dissipate heat away from the active area of the semiconductor package. In other implementations, the metal plating may be made of any other metal or metal alloy disclosed in this document. Also, in other implementations, the metal plating may not be plated, but may be formed by applying a metal foil to the die. In this implementation of a method of forming a semiconductor package, the metal plate 170 is applied only to the first side 148 of the die and not to the molding compound 160 as illustrated in FIGS. 7G and 9G. The metal plate on the first side of each die may act as a heat sink or assist with heat transfer to an external heat sink applied to the semiconductor package.

Referring to FIG. 8H, a plurality of bumps 164 is applied to the molding compound 160. The plurality of bumps 164 are mechanically and electrically coupled with the copper pillars 154 through metal plating 162 or interconnects. As illustrated, the plurality of die are singulated into individual semiconductor packages with a fan out structure. The bumps may be any electrical connector type disclosed in this document in various implementations.

Referring to FIG. 9A-9H, a method for manufacturing a semiconductor is illustrated. As illustrated in FIG. 9A, the method includes providing a wafer 172. The wafer includes a plurality of die 174 and each die has a first side and a second side. In various implementations, the wafers may include Si, GaN, SiC, or another suitable semiconductor material disclosed herein. For illustrative purposes, the wafer is illustrated as having each die separated by a scribe line 176. Each die includes an active area which are shown here as having different sizes. The active areas may include a source, drain, and a gate. In other implementations, the active areas may be the same size as illustrated in previous implementations.

Referring to FIG. 9B, the method may further include plating two or more copper pillars 178 on the second side of each of the plurality of die over a layer of aluminum 180. In various implementations, a different metal or metal alloy may be used in place of copper pillars. The different metal may include solder, Ni, Au, or other suitable metals or metal alloys disclosed herein. As shown in FIG. 9B, the die may be singulated from each other on the scribe lines 176 included on the wafer 172. In other implementations of a method of forming semiconductor packages, the die may be singulated later in the method.

Referring to FIG. 9C, the plurality of die may coupled to a carrier wafer 182 to provide support for later processing steps in the manufacturing process. The method may further include encapsulating the plurality of die 174 in a molding compound 184 (which may be any disclosed in this document). In various method implementations, the carrier wafer 182 may be removed after the molding compound has cured. The carrier may be removed through grinding, debonding, or other methods capable of removing the carrier without affecting the encapsulated die. As illustrated in FIG. 9D, the method may include grinding the molding compound 184 to a desired thickness and exposing a first side of the copper pillars 178.

Referring to FIG. 9E, the method further includes applying a plurality of metal plating 186 to the molding compound 184 on the second side of each of the die 174. The plurality of metal plating 186 may couple other elements to the copper pillars 178 which will be described below. The plurality of metal plating may include any metal that is an electrical conductor. As illustrated in FIG. 9E, the method may include applying a first passivation layer or a redistribution layer 188 to a second side of the molding compound 184. In various implementations, the method may further include applying a second passivation layer to the first passivation layer or to the redistribution layer.

Referring to FIG. 9F, the method may include thinning a first side 190 of each of the plurality of die 174. As previously described, thinning of the first side of the die together with the thinning of the molding compound may give the semiconductor package increased flexibility. Referring to FIG. 9G, the method may further include applying a coating 192 to the first side of the plurality of die. In various implementations, the coating may include a molding compound. In other implementations of a method of manufacturing a semiconductor packages, a coating may not be added if the first side of the die is not thinned.

Referring to FIG. 9H, a plurality of bumps 194 is applied to the molding compound 184. The plurality of bumps 194 are mechanically and electrically coupled with the copper pillars 178 through metal plating 186 or interconnects. The bumps may be any electrical connector disclosed herein in various implementations. As illustrated, the method further includes singulating the plurality of die into individual semiconductor packages with a fan out structure.

The implementations of methods of manufacturing semiconductor packages as described herein may also be used to form packages including multiple die as illustrated in FIGS. 4-6.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

1. A semiconductor package comprising:
one or more die comprising a first side and a second side opposite the first side, the first side of the die comprising one or more external connection points;
a layer of one or more metals comprised on the second side of the one or more die;
a second layer of one or more metals comprised on a first layer of one or more metals comprised on the first side of the die wherein the second layer is thicker than the first layer;
a molding compound encapsulating five sides of the one or more die and partially encapsulating the second layer of one or more metals;
a plurality of interconnects coupled to the second layer of one or more metals; and
two or more bumps coupled to the plurality of interconnects;
wherein at least a portion of each of the two or more bumps is outside a perimeter of the one or more die.

2. The semiconductor of claim 1, wherein the two or more bumps comprise one of copper pillars, balls, solder printed pads, and pads.

3. The semiconductor package of claim 1, further comprising one of a first passivation layer and a redistribution layer (RDL).

4. The semiconductor package of claim 3, further comprising a second passivation layer.

5. The semiconductor package of claim 1, further comprising a second molding compound on the first side of the one of more die.

6. The semiconductor package of claim 1, further comprising a metal coating on the one or more external connection points of the first side of the one or more die, the metal coating selected from the group consisting of titanium, nickel, vanadium, silver, copper, gold, aluminum, and any combination thereof.

7. The semiconductor package of claim 1, further comprising one of a copper plating and a copper frame on the one or more external connection points of the first side of the die.

8. A semiconductor package comprising:
one or more die comprising a first side and a second side opposite the first side;
two or more copper pillars coupled on the second side of the one or more die;
a layer of aluminum coupled between the one or more die and each of the two or more copper pillars;
a molding compound encapsulating five sides of the one or more die and partially encapsulating the two or more copper pillars;
a routing layer of metal coupled to the two or more copper pillars; and
a plurality of solder bumps coupled to the routing layer;
wherein at least a portion of the solder bumps are outside a perimeter of the one or more die.

9. The semiconductor package of claim 8, further comprising one of a first passivation layer and a redistribution layer (RDL).

10. The semiconductor package of claim 9, further comprising a second passivation layer.

11. The semiconductor package of claim 8, further comprising a second molding compound on the first side of the one or more die.

12. The semiconductor package of claim 8, further comprising a metal coating on the first side of the die, the metal coating selected from the group consisting of titanium, nickel, vanadium, silver, copper, gold, aluminum, and any combination thereof.

13. The semiconductor package of claim 8, further comprising one of a copper plating and a copper frame on a first side of the die.

14.-20. (canceled)
